(19) United States
(12) Patent Application Publication
(10) Pub. No.: US 2007/0151847 A1
(43) Pub. Date: Jul. 5, 2007

(54) MAGNETRON

(75) Inventor: Jong-Soo Lee, Anyang (KR)

Correspondence Address: GREENBLUM & BERNSTEIN, P.L.C., 1950 ROLAND CLARKE PLACE, RESTON, VA, 20191, US

(73) Assignee: LG Electronics Inc., Seoul (KR)

(21) Appl. No.: 11/611,523

(22) Filed: Dec. 15, 2006

(30) Foreign Application Priority Data
Dec. 30, 2005 (KR) 10-2005-0136160

(51) Int. Cl. C23C 14/00

(52) U.S. Cl. 204/298.19

(57) ABSTRACT

A magnetron comprises an anode, a cathode disposed at a center of the anode, a plurality of vanes radially protruding from an inner surface of the anode towards the cathode, and an upper end shield and a lower end shield respectively coupled to an upper end and a lower end of the cathode so that a length of an effective heating portion of the cathode may be less than a height of the vane. A heating power for the cathode is reduced thus to decrease an input power for the same output, thereby enhancing an efficiency of the magnetron

### RELATED APPLICATION

The present disclosure relates to subject matter contained in priority Korean Application No. 10-2005-0136160, filed on Dec. 30, 2005, which is herein expressly incorporated by reference in its entirety.

### BACKGROUND OF THE INVENTION

1. Field of the Invention

The present invention relates to a magnetron, and more particularly, to a magnetron capable of enhancing an efficiency thereof by reducing an input power for the same output power by reducing a heating power for a cathode.

2. Description of the Background Art

Generally, a magnetron is applied to a microwave range, a plasma lighting device, a dryer, and other high frequency system. The magnetron includes a high frequency generating unit for generating high frequency energy by an electromagnetic field, an input unit for applying power to the high frequency generating unit, and an output unit for emitting high frequency energy generated from the high frequency generating unit.

FIG. 1 is a sectional view showing a magnetron in accordance with the conventional art, FIG. 2 is an enlargement view showing a main part of FIG. 1, and FIG. 3 is a side view showing a cathode of FIG. 2.

As shown, the magnetron includes a high frequency generating unit 100 for generating high frequency energy, an input unit 200 formed at a lower side of the high frequency generating unit 100 for applying power to the high frequency generating unit 100, and an output unit 300 formed at an upper side of the high frequency generating unit 100 for emitting high frequency energy generated from the high frequency generating unit 1C0.

The high frequency generating unit 100 includes a yoke plate 111 having a square box shape, an anode 121 having a cylindrical shape and disposed at the center of the yoke plate 111, an A-seal 131 and an F-seal 141 respectively formed at an upper end and a lower end of the anode 121, an upper magnet 133 and an upper magnetic pole 135 disposed at an upper side of the anode 121, a lower magnet 143 and a lower magnetic pole 145 disposed at a lower side of the anode 121, and a cathode 151 disposed at the center of the anode 121.

A plurality of cooling fins 113 are laminated to each other in the yoke plate 111 so as to emit heat from the anode 121.

A plurality of vanes 125 are protruding towards the cathode 151 in the anode 121 so that an electron moving space 122 can be formed between the anode 121 and the cathode 151. A ceramic stem 147 is installed at a lower end of the F-seal 141. An inner space formed by the ceramic stem 147, the anode 121, the A-seal 131, and the F-seal 141 is maintained as a vacuum state.

The cathode 151 is formed to have a spiral shape. An upper end shield 155 and a lower end shield 165 are coupled to an upper end and a lower end of the cathode 151, respectively. A center lead 161 is arranged to penetrate the lower end shield 165, and a side lead 163 is connected to one side of the lower end shield 165. The center lead 161 penetrates the lower end shield 165 thus to be coupled to the upper end shield 155 via the center of the cathode 151. The upper end shield 155 is integrally coupled to an upper end of the cathode 151.

The input unit 200 includes a filter box 211 formed at a lower side of the yoke plate 111, a condenser 213 coupled to one side of the filter box 211, a choke coil 215 disposed in the filter box 211 and connected to the condenser 213, and an external connection lead 217 extending from the choke coil 215 and electrically connected to the center lead 161 and the side lead 163.

The output unit 300 includes an antenna feeder 311 connected to the vane 125, an A-ceramic 313 disposed at an upper side of the A-seal 131 and having the antenna feeder 311 therein, and an antenna cap 315 disposed at an upper side of the A-ceramic 313

However, the conventional magnetron has the following problem. In a state of a low output power such as 100 W˜300 W, a heating power for the cathode 151 occupied in an entire input power for the same output power is increased, Accordingly, an efficiency of the magnetron is decreased.

### SUMMARY OF THE INVENTION

Therefore, an object of the present invention is to provide a magnetron capable of enhancing an efficiency thereof by decreasing an input power for the same output power by decreasing a heating power for a cathode.

To achieve these and other advantages and in accordance with the purpose of the present invention, as embodied and broadly described herein, there is provided a magnetron, comprising an anode; a cathode disposed at the center of the anode, a plurality of vanes radially protruding from an inner surface of the anode towards the cathode; and an upper end shield and a lower end shield respectively coupled to an upper end and a lower end of the cathode so that a length of an effective heating portion of the cathode may be less than a height of the vane.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a sectional view showing a magnetron in accordance with the conventional art;

FIG. 2 is an enlargement view showing a main part of FIG. 1;

FIG. 3 is a side view showing a cathode of FIG. 2;

FIG. 4 is a sectional view showing a magnetron according to a first embodiment of the present invention;

FIG. 5 is an enlargement view showing a main part of FIG. 4;

FIG. 6 is a side view showing a coupled state of an upper end shield of FIG. 4;

FIGS. 7A to 7C respectively show a heating power for a cathode, a dark current, and an efficiency of the magnetron according to a ratio between a length of an effective heating portion of a cathode and a height of a vane;

FIG. 8 is a sectional view showing a magnetron according to a second embodiment of the present invention;

FIG. 9 is an enlargement view showing a main part of FIG. 8;

FIG, 10 is a side view showing a cathode of FIG. 8;

FIG. 11 is a sectional view showing a magnetron according to a third embodiment of the present invention; and

FIG. 12 is an enlargement view showing a main part of FIG. 11.

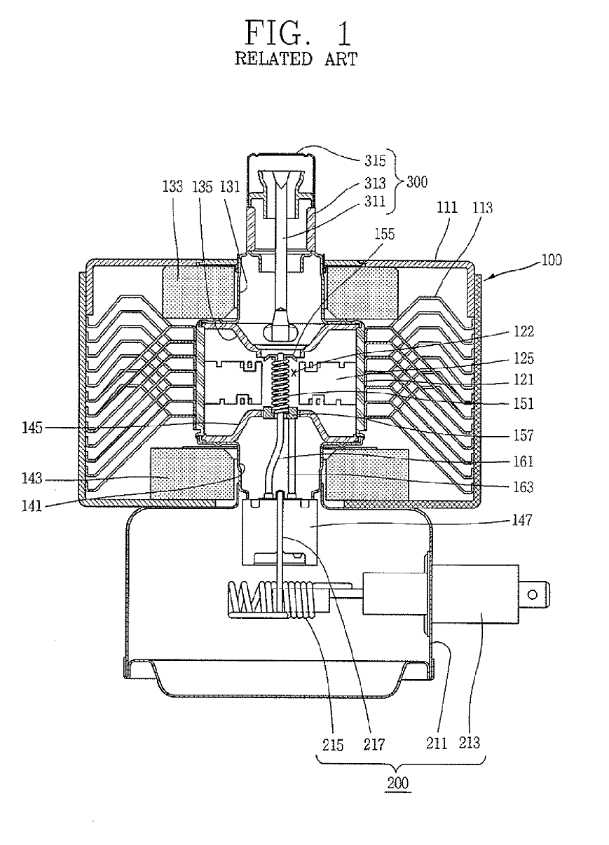

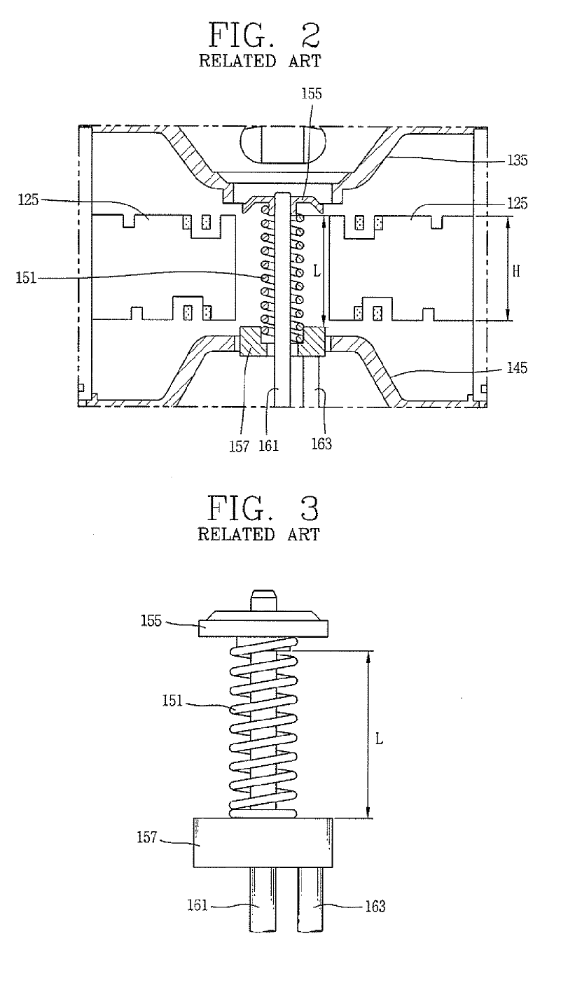

### DETAILED DESCRIPTION OF THE INVENTION

Reference will now be made in detail to the preferred embodiments of the present invention, examples of which are illustrated in the accompanying drawings

Hereinafter, a magnetron according to a first embodiment of the present invention will be explained in more detail.

The same reference numerals will be given to the same parts as the aforementioned parts.

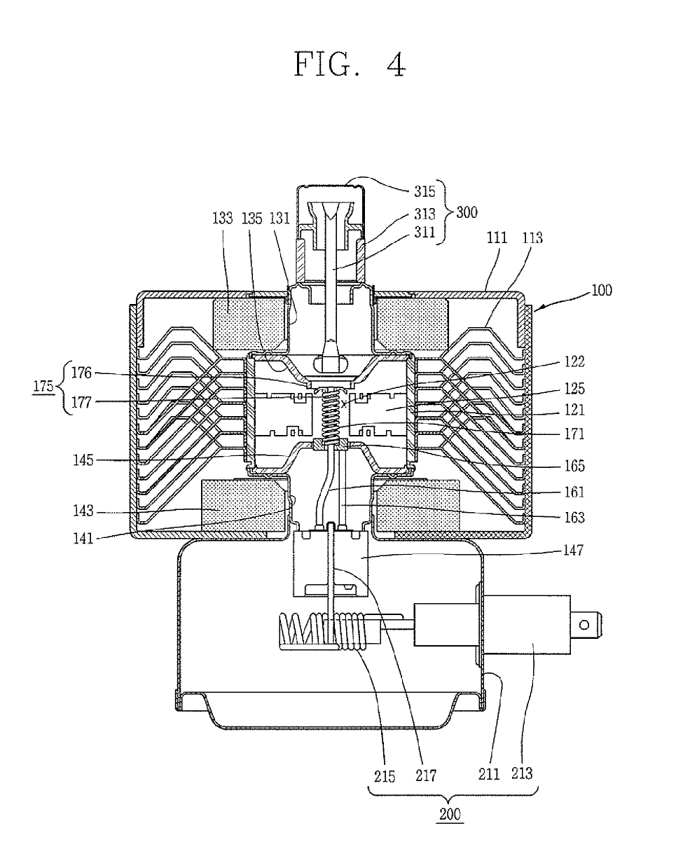

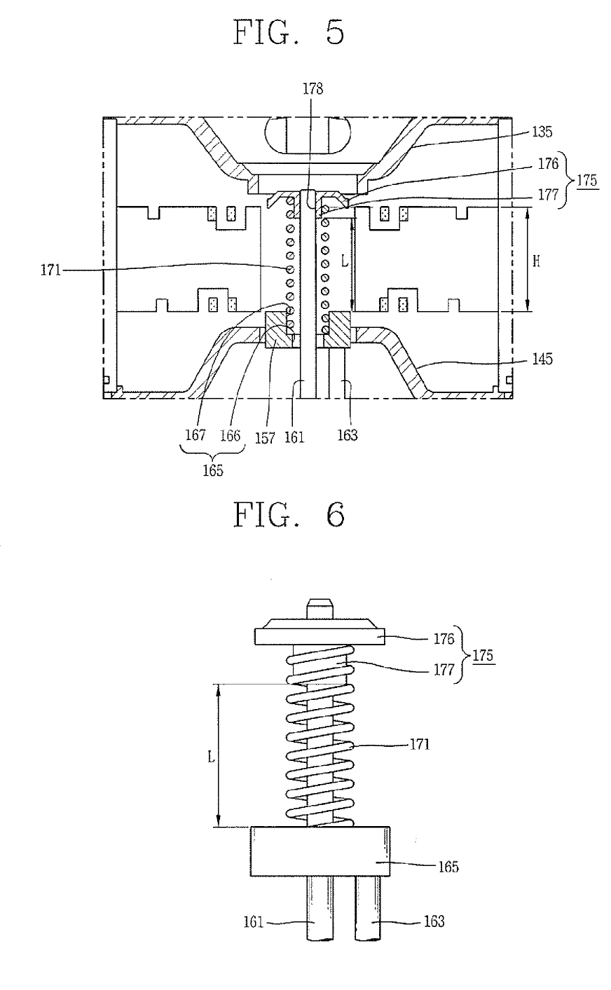

As shown in FIGS. 4 to 6, the magnetron according to the present invention comprises a high frequency generating unit 100 interposed between an input unit 200 for providing power and an output unit 300 for outputting high frequency energy, for generating high frequency. The high frequency generating unit 100 includes an anode having a cylindrical shape; a plurality of vanes 125 disposed in the anode 121; an upper magnetic pole 135 and a lower magnetic pole 145 respectively disposed at an upper side and a lower side of the anode 121; a cathode 171 having a spiral shape, disposed at the center of the anode 121, and passing a center lead 161 therethrough; a lower end shield 165 for passing the center lead 161, and connected to a lower end of the cathode 171; and an upper end shield 175 including a shielding portion 176 and a coupling portion 177, the shielding portion 176 having a size larger than that of the cathode 171 and disposed at an upper end of the cathode 171, and the coupling portion 177 having the center lead 161 therein and coupled into the cathode 171 so that a length L of an effective heating portion of the cathode 171 may be less than a height of the vane 125.

One end of a plurality of laminated cooling fins 113 is coupled to an outer surface of the anode 121, and another end of the cooling fins 113 contacts an inner surface of a yoke plate 111. The yoke plate 111 has a square box shape having two opened sides. The output unit 300 for emitting high frequency energy generated from the high frequency generating unit 100 is formed at an upper side of the yoke plate 111. The input unit 200 for applying power to the high frequency generating unit 100 is formed at a lower side of the yoke plate 111.

The input unit 200 includes a filter box 211 having a square shape, a condenser 213 coupled to one side of the filter box 211, a choke coil 215 disposed in the filter box 211 and having one end connected to the condenser 213, and an external connection lead 217 connected to another end of the choke coil 215.

The output unit 300 includes an A-ceramic 313 disposed at an upper side of the yoke plate 111, an antenna feeder 311 having one end connected to the vane 125 and having another end disposed in the A-ceramic 313, and an antenna cap 315 disposed at an upper end of the A-ceramic 313 and having the antenna feeder 311 therein.

An upper magnet 133 an upper magnetic pole 135, and an A-seal 131 are installed at an upper side of the anode 121. Also, a lower magnet 143, a lower magnetic pole 145, and an F-seal 141 are installed at a lower side of the anode 121 A ceramic stem 147 is installed at a lower end of the F-seal 141, and the eternal connection lead 217 is inserted into the ceramic stem 147.

The cathode 171 is concentrically installed at the center of the anode 121. A plurality of the vanes 125 are radially installed at an inner surface of the anode 121 so that an electron moving space 122 can be formed between the anode 121 and the cathode 171.

The cathode 171 has a cylindrical coil shape. The upper end shield 175 and the lower end shield 165 are electrically connected to an upper end and a lower end of the cathode 171, respectively. The lower end shield 165 is provided with a passing hole 166 for passing the center lead 161 without contact, the center lead 161 having one end connected to the external connection lead 217. An insertion portion 167 for inserting a lower end of the cathode 171 is formed at an upper portion of the lower end shield 165. A side lead 163 has one end connected to the external connection lead 217, and has another end connected to one side of the lower end shield 165.

The upper end shield 175 includes a shielding portion 176 having a size larger than a diameter of a coil of the cathode 171 and arranged at an upper side of the cathode 1717 and a coupling portion 177 downwardly protruding from a lower center of the shielding portion 176. The coupling portion 177 is provided with a coupling hole 178 for coupling the center lead 161 at the center thereof. The coupling portion 177 is inserted into an upper end of the cathode 171 so that a length L of an effective heating portion of the cathode 171 may be less than a height H of the vane 125. Accordingly, an outer surface of the coupling portion 177 is connected to the cathode 171. Preferably, a ratio between the length L of the effective heating portion of the cathode 171 for emitting thermo-electron and the height H of the vane 125 is within a range of 0.80˜0.87.

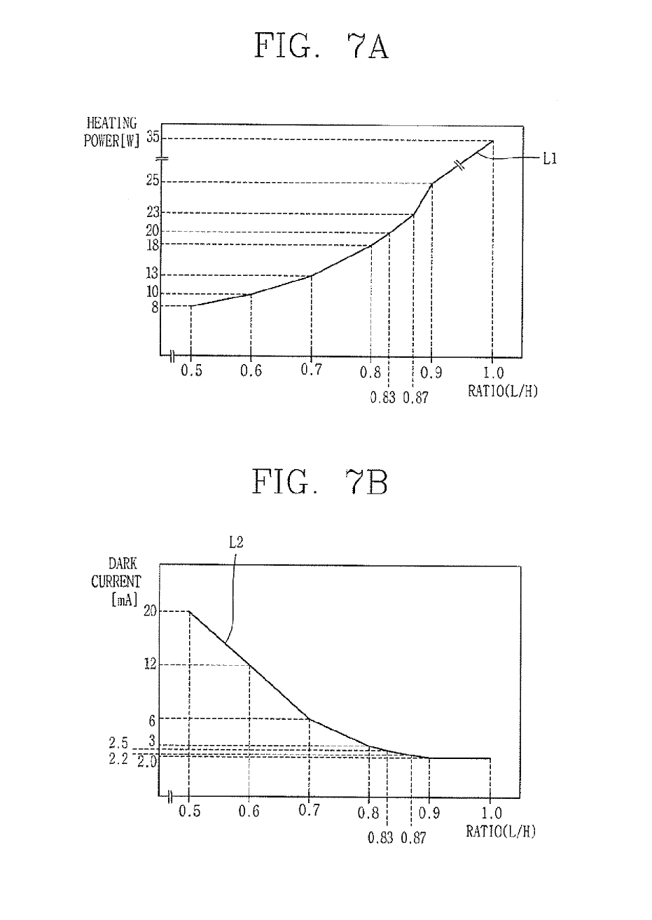

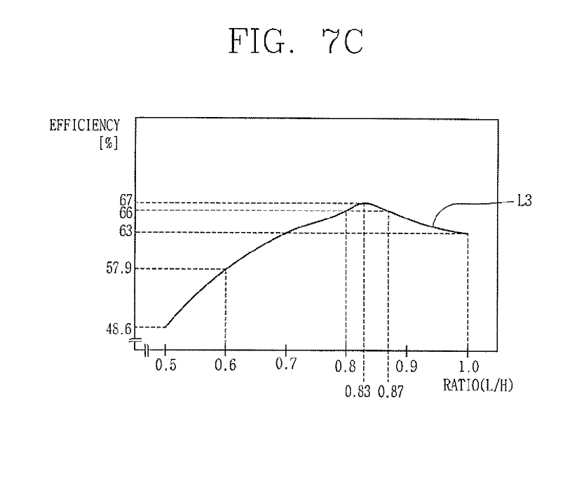

Hereinafter, with reference to FIGS. 7A to 7C, a dark current according to a ratio between the length L of the effective heating portion of the cathode 171 and the height H of the vane 125 (L/H), a heating power for the cathode 171 according to the L/H, and an efficiency of the magnetron according to the L/H will be explained.

The heating power for the cathode 171 is increased when the length L of the effective heating portion of the cathode 171 is increased. As shown in FIG. 7A, the heating power for the cathode 171 is varied according to the L/H as indicated by the straight line L1.

As shown in FIG. 78, the dark current is varied according to the L/H as indicated by the curved line L2. Herein, the dark current is drastically increased when the L/H is less than 0.8.

As shown in FIG. 7C, the efficiency of the magnetron is varied according to the L/H as indicated by the curved line L3. Herein, the efficiency of the magnetron is increased when the L/H is increased within a certain period, and has the optimum value when the L/H has a value corresponding to 0.80˜0.87.

For instance, in a state that an operating voltage is 4 KV, an operating current is 70 mA, and an output from the magnetron is 200 W, if the L/H is 1, the heating power for the cathode 171 is 35 W, the dark current is 2.0 mA, an input to the magnetron is 315 W, and the efficiency of the magnetron is 63%. However, if the ratio L/H is 0.83 under the same conditions the heating power for the cathode 171 is 20 W, the dark current is 2.5 mA, the input to the magnetron is 300 W, and the efficiency of the magnetron is 67%.

If the ratio L/H is 0.8 under the same conditions, the heating power for the cathode 171 is 18 W, the dark current is 3 mA, and the efficiency of the magnetron is 66%.

If the ratio L/H is 0.87 under the same conditions, the heating power for the cathode 171 is 23 W, the dark current is 2.2 mA, and the efficiency of the magnetron is 66%.

When power is supplied to the center lead 161 and the side lead 163 through the external connection lead 217 of the input unit 200, the cathode 171 emits thermo-electrons to the electron moving space 122. Then, the emitted thermo-electrons interacts with magnetic energy due to the upper magnetic pole 135 and the lower magnetic pole 145 thus to be absorbed into the anode 121, thereby generating microwave having high frequency energy. The generated microwave is emitted outwardly through the antenna feeder 311, thereby performing heating and drying operation or emitting light.

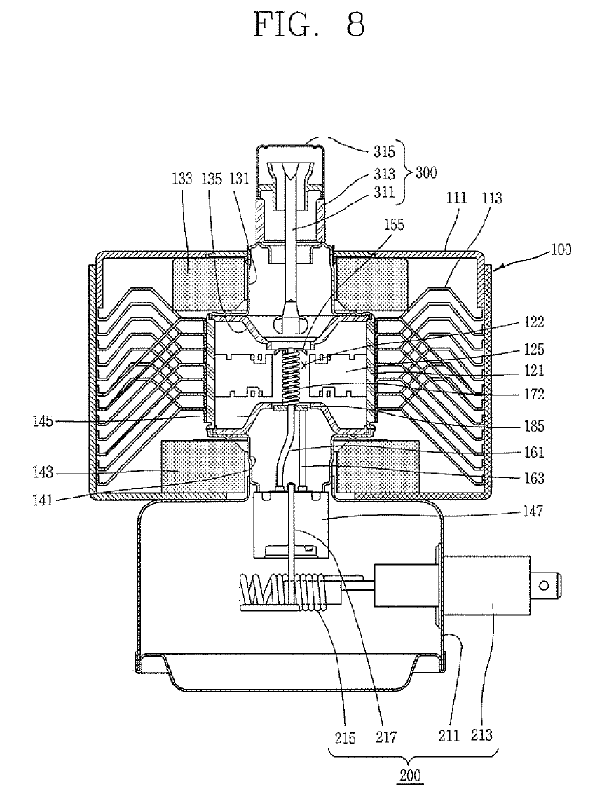

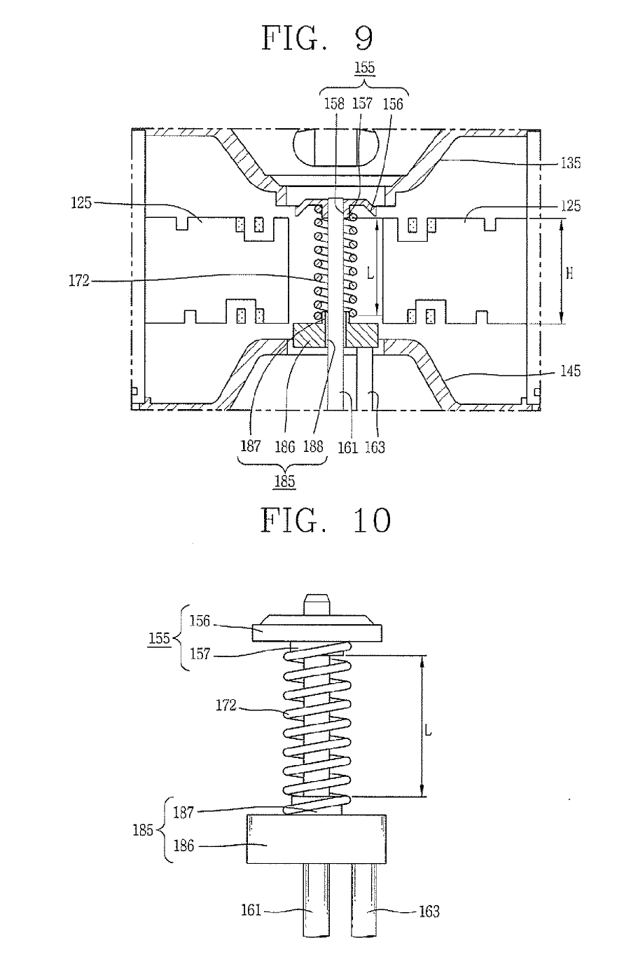

FIG. 8 is a sectional view showing a magnetron according to a second embodiment of the present invention, FIG. 9 is an enlargement view showing a main part of FIG. 8, and FIG. 10 is a side view showing a cathode of FIG. 8.

As shown, the magnetron according to the second embodiment of the present invention comprises an anode 121, a cathode 172 disposed at the center of the anode 121 and passing a center lead 161 therethrough, a plurality of vanes 125 radially protruding from an inner surface of the anode 121 towards the cathode 172, and an upper end shield 155 and a lower end shield 185 respectively coupled to an upper end and a lower end of the cathode 172 so that a length L of an effective heating portion of the cathode 172 may be less than a height H of the vane 125.

A yoke plate 111 is provided at an outer side of the anode 121, and a plurality of cooling fins 113 are coupled to inside of the anode 121 and the yoke plate 111.

An input unit 200 for applying power to the high frequency generating unit 100 is formed at a lower side of the yoke plate 111. An output unit 300 for emitting high frequency energy generated from the high frequency generating unit 100 is formed at an upper side of the yoke plate 111.

The input unit 200 includes a filter box 211 having a square shape, a condenser 213 coupled to one side of the filter box 211, a choke coil 215 disposed in the filter box 211 and having one end connected to the condenser 213, and an external connection lead 217 connected to another end of the choke coil 215.

The output unit 300 includes an A-ceramic 313 disposed at an upper side of the yoke plate 111, an antenna feeder 311 having one end connected to the vane 125 and having another end disposed in the A-ceramic 313, and an antenna cap 315 disposed at an upper end of the A-ceramic 313 and having the antenna feeder 311 therein.

An upper magnet 133, an upper magnetic pole 135, and an A-seal 131 are installed at an upper side of the anode 121. Also, a lower magnet 143, a lower magnetic pole 145, and an F-seal 141 are installed at a lower side of the anode 121. A ceramic stem 147 is installed at a lower end of the F-seal 141, and the eternal connection lead 217 is inserted into the ceramic stem 147.

The cathode 172 is concentrically installed at the center of the anode 121. A plurality of the vanes 125 are radially installed at an inner surface of the anode 121 so that an electron moving space 122 can be formed between the anode 121 and the cathode 172.

The cathode 172 has a cylindrical coil shape. The upper end shield 155 and the lower end shield 185 are electrically connected to an upper end and a lower end of the cathode 172, respectively.

The upper end shield 155 includes a shielding portion 156 having a size larger than the cathode 172, and a coupling portion 157 downwardly protruding from the shielding portion 156. The coupling portion 157 is provided with a coupling hole 158 for coupling the center lead 161 therein. An upper end of the cathode 172 is coupled to an outer surface of the coupling portion 157.

The lower end shield 185 includes a shielding portion 186 having a size larger than the cathode 172, and a coupling portion 187 upwardly protruding from an upper surface of the shielding portion 186 thus to be inserted into a lower end of the cathode 172. Since the lower end of the cathode 172 contacts the upper surface of the lower end shield 185, the length of the cathode 172 is shortened.

The shielding portion 186 and the coupling portion 187 are respectively provided with a passing hole 188 for passing the center lead 161 without contact. A side lead 163 is connected to one side of the shielding portion 186. The lower end shield 185 is disposed so that an upper surface of the shielding portion 186 and a lower end of the vane 125 have the same height. Preferably, the coupling portion 187 is protrudingly-formed so that a ratio (L/H) between a length L of an effective heating portion of the cathode 172 and a height H of the vane 125 is within a range of 0.80˜0.87, thereby decreasing a heating power for the cathode 172.

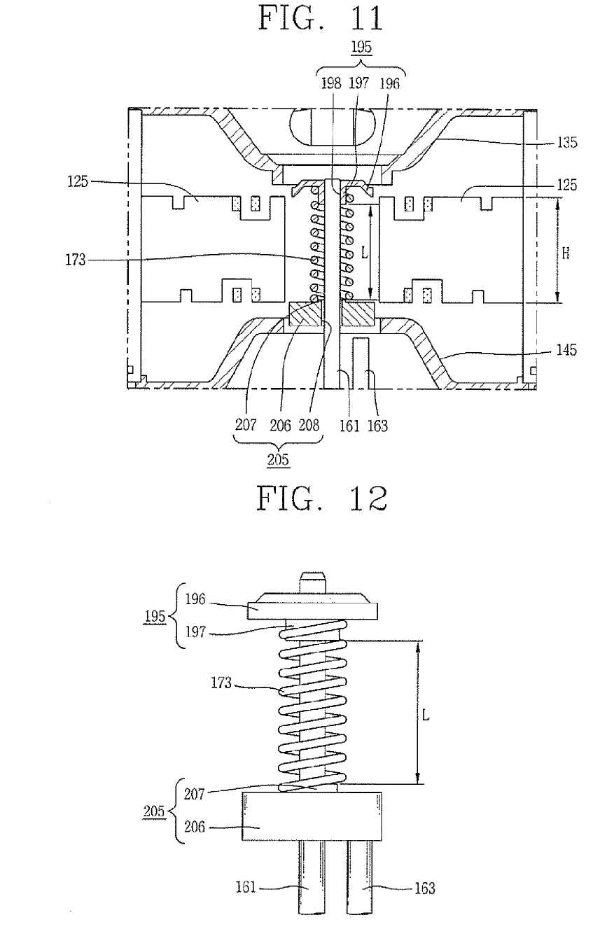

FIG. 11 is a sectional view showing a magnetron according to a third embodiment of the present invention, and FIG. 12 is an enlargement view showing a main part of FIG. 11.

As shown, the magnetron according to the third embodiment of the present invention comprises an anode 121, a cathode 173 disposed at the center of the anode 121 and passing a center lead 161 therethrough, a plurality of vanes 125 radially protruding from an inner surface of the anode 121 towards the cathode 173, and an upper end shield 195 and a lower end shield 205 respectively coupled to an upper end and a lower end of the cathode 173 so that a length L of an effective heating portion of the cathode 173 may be less than a height H of the vane 125.

A yoke plate 111 is provided at an outer side of the anode 121, and a plurality of cooling fins 113 are coupled to inside of the anode 121 and the yoke plate 111.

An input unit 200 for applying power to the high frequency generating unit 100 is formed at a lower side of the yoke plate 111. The input unit 200 includes a filter box 21 1, a condenser 213, a choke coil 215, and an external connection lead 217. An output unit 300 for emitting high frequency energy generated from the high frequency generating unit 100 is formed at an upper side of the yoke plate 111. The output unit 300 includes an A-ceramic 313, an antenna feeder 311, and an antenna cap 315.

An upper magnet 133, an upper magnetic pole 135, and an A-seal 131 are installed at an upper side of the anode 121. Also, a lower magnet 143, a lower magnetic pole 145, and an F-seal 141 are installed at a lower side of the anode 121. A ceramic stem 147 is installed at a lower end of the F-seal 141, and the eternal connection lead 217 is inserted into the ceramic stem 147.

The cathode 173 is concentrically installed at the center of the anode 121. A plurality of the vanes 125 are radially installed at an inner surface of the anode 121 so that an electron moving space 122 can be formed between the anode 121 and the cathode 173.

The cathode 173 has a cylindrical coil shape. The upper end shield 195 and the lower end shield 205 are electrically connected to an upper end and a lower end of the cathode 173, respectively.

The upper end shield 195 includes a shielding portion 196 having a size larger than the cathode 173, and a coupling portion 197 downwardly protruding from the shielding portion 196. The coupling portion 197 is provided with a coupling hole 198 for coupling the center lead 161 therein. An upper end of the cathode 173 is coupled to an outer surface of the coupling portion 197.

The lower end shield 205 includes a shielding portion 206 having a size larger than a diameter of a coil of the cathode 173, and a coupling portion 207 upwardly protruding from an upper surface of the shielding portion 206 thus to be inserted into a lower end of the cathode 173. The shielding portion 206 and the coupling portion 207 are respectively provided with a passing hole 208 at each center thereof, the passing hole 208 for passing the center lead 161 without contact A side lead 163 is connected to one side of the shielding portion 206. The shielding portions 196 and 206 of the upper end shield 195 and the lower end shield 205 are respectively arranged so as to have the same height as the vane 125. Preferably, the coupling portions 197 and 207 are protrudingly-formed so that a ratio (L/H) between a length L of an effective heating portion of the cathode 173 and a height H of the vane 125 is within a range of 0.80˜0.87, thereby decreasing a heating power for the cathode 173.

As aforementioned, in the present invention, the length of the effective heating portion of the cathode is decreased thus to reduce the heating power for the cathode, thereby enhancing the efficiency of the magnetron.

Furthermore, in the present invention, not only the length of the effective heating portion of the cathode but also the length of the cathode itself can be reduced, thereby facilitating fabrication for the magnetron and reducing the fabrication cost,

As the present invention may be embodied in several forms without departing from the spirit or essential characteristics thereof it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalents of such metes and bounds are therefore intended to be embraced by the appended claims.

What is claimed is:

1. A magnetron, comprising,
an anode;
a cathode disposed at a center of the anode;
a plurality of vanes radially protruding from an inner surface of the anode towards the cathode; and
an upper end shield and a lower end shield respectively coupled to an upper end and a lower end of the cathode so that a length of an effective heating to portion of the cathode may be less than a height of the vane.

2. The magnetron of claim 1, wherein the cathode has a cylindrical coil shape, and the upper end shield partially overlaps with the cathode.

3. The magnetron of claim 2, wherein the upper end shield comprises:
a shielding portion having a size larger than the cathode, and arranged at the same position or at an upper position as/than an upper end of the vane; and
a coupling portion protruding from the shielding portion thus to be inserted into the cathode.

4. The magnetron of claim 3, wherein the upper end shield and the lower end shield are coupled to the cathode so that a ratio (L/H) between a length (L) of an effective heating portion of the cathode and a height (H) of the vane may be within a range of 0.80˜0.87.

5. The magnetron of claim 3, wherein the lower end shield is provided with an insertion hole for inserting the lower end shield at a center thereof and an upper surface of the lower end shield is arranged at the same position or at a lower position as/than a lower end of the vane.

6. The magnetron of claim 2, wherein the lower end shield comprises:
a shielding portion having a size larger than the cathode, and arranged at a lower end of the cathode: and
a coupling portion upwardly protruding from the shielding portion thus to overlap with the cathode.

7. The magnetron of claim 6, wherein the upper end shield and the lower end shield are coupled to the cathode so that a ratio (L/H) between a length (L) of an effective heating portion of the cathode and a height (H) of the vane may be within a range of 0.80˜0.87.

8. The magnetron of claim 2, wherein the upper end shield comprises:
a shielding portion having a size larger than the cathode, and arranged at the same position or at an upper position as/than an upper end of the vane; and
a coupling portion protruding from the shielding portion thus to be inserted into the cathode
wherein the lower end shield comprises:
a shielding portion having a size larger than the cathode, and arranged at a lower end of the cathode; and
a coupling portion upwardly protruding from the shielding portion thus to overlap with the cathode.

9. The magnetron of claim 8, wherein the upper end shield and the lower end shield are coupled to the cathode so that a ratio (L/H) between a length (L) of an effective heating portion of the cathode and a height (H) of the vane may be within a range of 0.80˜0.87.

10. The magnetron of claim 1, wherein the upper end shield and the lower end shield are coupled to the cathode so that a ratio (L/H) between a length (L) of an effective heating portion of the cathode and a height (H) of the vane may be within a range of 0.80˜0.87
